(19) United States
(12) Patent Application Publication
(10) Pub. No.: US 2015/0087093 A1
(43) Pub. Date: Mar. 26, 2015

(54) METHOD AND SYSTEM FOR MANUFACTURING DISPLAY DEVICE

(71) Applicant: Kabushiki Kaisha Toshiba, Minato-ku (JP)

(72) Inventors: Tatsunori SAKANO, Kawasaki (JP); Kentaro Miura, Kawasaki (JP); Tomomasa Ueda, Yokohama (JP); Nobuyoshi Saito, Ota (JP); Shintaro Nakano, Kawasaki (JP); Yuya Maeda, Kawasaki (JP); Hajime Yamaguchi, Kawasaki (JP)

(73) Assignee: Kabushiki Kaisha Toshiba, Minato-ku (JP)

(21) Appl. No.: 14/458,422

(22) Filed: Aug. 13, 2014

(30) Foreign Application Priority Data
Sep. 20, 2013 (JP) 2013-195063

(51) Int. Cl. H01L 27/32; B32B 37/24; H01L 51/52; H01L 51/56; H01L 51/00

(52) U.S. Cl. CPC H01L 27/3244; H01L 51/56; H01L 51/0024; H01L 51/524; B32B 37/24; B32B 2037/243; B32B 38/0008
USPC 438/27; 156/390; 156/379.6

(57) ABSTRACT

According to one embodiment, a method is disclosed for manufacturing a display device. The method can include forming a first resin layer on a substrate. The method can include forming a display layer on the first resin layer. The display layer includes a plurality of pixels arranged in a direction perpendicular to a stacking direction of the first resin layer and the display layer. Each of the pixels includes a first electrode provided on the first resin layer, an organic light emitting layer provided on the first electrode, and a second electrode provided on the organic light emitting layer. The method can include bonding a second resin layer onto the display layer via a bonding layer. The method can include removing the substrate. The method can include increasing a density of the bonding layer.

### CROSS-REFERENCE TO RELATED APPLICATIONS

This application is based upon and claims the benefit of priority from Japanese Patent Application No. 2013-195063, filed on Sep. 20, 2013; the entire contents of which are incorporated herein by reference.

### FIELD

Embodiments described herein relate generally to a method and a system for manufacturing display device.

### BACKGROUND

There is known a display device based on electroluminescence (EL) elements. The display device based on electroluminescence elements is required to be lightweight and large-scale. In addition, there are high requirements such as long-term reliability, high freedom of shape, and capability of curved surface display. Thus, as a substrate used in the display device, a resin layer such as a transparent plastic layer is drawing attention instead of a glass substrate, which is heavy, fragile, and difficult to form in large area. In a method for manufacturing the display device, a resin layer is provided on a support substrate such as a glass substrate. A circuit and a display layer are formed on the resin layer. Then, the support substrate is peeled from the resin layer to form the display device. In such a method for manufacturing the display device, improvement in reliability is desired.

### BRIEF DESCRIPTION OF THE DRAWINGS

FIG. 1 is a sectional view schematically showing a display device according to a first embodiment;

FIGS. 2A to 2C are sectional views schematically showing a sequential process for manufacturing a display device according to the first embodiment;

FIGS. 3A and 3B are sectional views schematically showing a sequential process for manufacturing a display device according to the first embodiment;

FIG. 4 is a flow chart schematically showing the method for manufacturing a display device according to the first embodiment;

FIG. 5 is a sectional view schematically showing a display device according to a second embodiment;

FIGS. 6A to 6C are sectional views schematically showing a sequential process for manufacturing a display device according to the second embodiment;

FIG. 7 is a sectional view schematically showing a sequential process for manufacturing a display device according to the second embodiment; and

FIG. 8 is a block diagram schematically showing a manufacturing system according to a third embodiment.

### DETAILED DESCRIPTION

According to one embodiment, a method is disclosed for manufacturing a display device. The method can include forming a first resin layer on a substrate. The method can include forming a display layer on the first resin layer. The display layer includes a plurality of pixels arranged in a direction perpendicular to a stacking direction of the first resin layer and the display layer. Each of the pixels includes a first electrode provided on the first resin layer, an organic light emitting layer provided on the first electrode, and a second electrode provided on the organic light emitting layer. The method can include bonding a second resin layer onto the display layer via a bonding layer. The method can include removing the substrate. The method can include increasing a density of the bonding layer.

According to another embodiment, a system for manufacturing a display device includes a first processing unit, a second processing unit, a third processing unit, a fourth processing unit, and a fifth processing unit. The first processing unit is configured to form a first resin layer on a substrate. The second processing unit is configured to form a display layer on the first resin layer. The display layer includes a plurality of pixels arranged in a direction perpendicular to a stacking direction of the first resin layer and the display layer. Each of the pixels includes a first electrode provided on the first resin layer, an organic light emitting layer provided on the first electrode, and a second electrode provided on the organic light emitting layer. The third processing unit is configured to bond a second resin layer onto the display layer via a bonding layer. The fourth processing unit is configured to remove the substrate. The fifth processing unit is configured to increase a density of the bonding layer.

Various embodiments will be described hereinafter with reference to the accompanying drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In the present description and the drawings, components similar to those described previously with reference to earlier figures are labeled with like reference numerals, and the detailed description thereof is omitted appropriately.

### First Embodiment

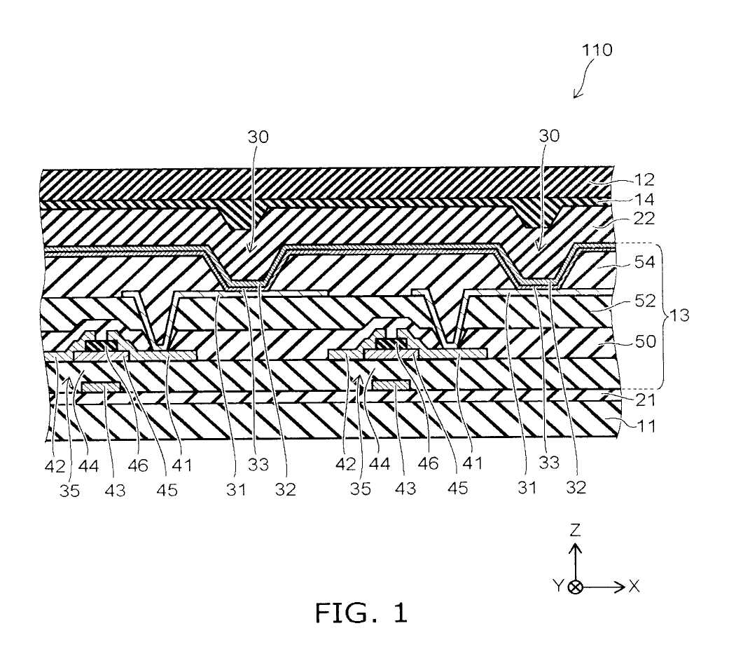

FIG. 1 is a sectional view schematically showing a display device according to a first embodiment.

As shown in FIG. 1, the display device 110 includes a first resin layer 11, a second resin layer 12, a display layer 13, and a bonding layer 14. In the display device 110, for instance, the display layer 13 is supported by the first resin layer 11 and the second resin layer 12. The display device 110 has e.g. flexibility. The display device 110 is e.g. a flexible display device.

The display layer 13 is provided on the first resin layer 11. The second resin layer 12 is provided on the display layer 13. The bonding layer 14 is provided between the display layer 13 and the second resin layer 12. The second resin layer 12 is bonded onto the display layer 13 by the bonding layer 14.

In this example, the display device 110 further includes a first sealing layer 21 and a second sealing layer 22. The first sealing layer 21 and the second sealing layer 22 are provided as necessary, and can be omitted. The first sealing layer 21 is provided on the first resin layer 11. In this example, the display layer 13 is provided on the first sealing layer 21. The second sealing layer 22 is provided on the display layer 13. In this example, the bonding layer 14 is provided on the second sealing layer 22. That is, in this example, the second resin layer 12 is bonded to the second sealing layer 22 via the bonding layer 14.

The first resin layer 11 has flexibility. In this example, the first resin layer 11 further has optical transmissivity. The first resin layer 11 has a thermal characteristic that is not substantially changed in e.g. the formation of the display layer 13. The first resin layer 11 is made of e.g. polyimide.

The first sealing layer 21 suppresses e.g. penetration of moisture and impurities. The first sealing layer 21 protects e.g. the display layer 13 from moisture, impurities and the like. The first sealing layer 21 is made of e.g. a material having flexibility, optical transmissivity, and gas barrier property. The first sealing layer 21 is made of e.g. silicon oxide film, silicon nitride film, or silicon oxynitride film.

The display layer 13 includes a plurality of pixels 30. The plurality of pixels 30 are arranged in directions perpendicular to the stacking direction of the first resin layer 11 and the display layer 13.

Here, the direction parallel to the stacking direction of the first resin layer 11 and the display layer 13 is referred to as Z-axis direction. One direction perpendicular to the Z-axis direction is referred to as X-axis direction. The direction perpendicular to the X-axis direction and the Z-axis direction is referred to as Y-axis direction.

The plurality of pixels 30 are arranged in e.g. the X-axis direction and the Y-axis direction. The plurality of pixels 30 are arranged in e.g. a two-dimensional matrix in the plane (X-Y plane) perpendicular to the stacking direction.

Each of the plurality of pixels 30 includes a first electrode 31, a second electrode 32, and an organic light emitting layer 33. The first electrode 31 is provided on the first resin layer 11. The organic light emitting layer 33 is provided on the first electrode 31. The second electrode 32 is provided on the organic light emitting layer 33. The first electrode 31 has e.g. optical transmissivity. The second electrode 32 has e.g. optical reflectivity. The optical reflectance of the second electrode 32 is higher than the optical reflectance of the first electrode 31.

The organic light emitting layer 33 is electrically connected to each of the first electrode 31 and the second electrode 32. Thus, a current flows in the organic light emitting layer 33 by applying a voltage between the first electrode 31 and the second electrode 32. Accordingly, a current is passed in the organic light emitting layer 33 through the first electrode 31 and the second electrode 32. Thus, light is emitted from the organic light emitting layer 33.

In this example, the light emitted from the organic light emitting layer 33 is transmitted through the first electrode 31 and emitted outside from the first resin layer 11. That is, in this example, the display device 110 is of what is called the bottom emission type. For instance, the first electrode 31 may be optically reflective, the second electrode 32 may be optically transmissive, and light may be emitted outside from the second resin layer 12. That is, the display device 110 may be of what is called the top emission type.

The pixel 30 is e.g. a portion of the display device 110 where light is emitted from the organic light emitting layer 33. In the display device 110, light emission of each of the pixels 30 arranged in a two-dimensional matrix is controlled. Thus, an image can be displayed in the display device 110.

In this example, the display layer 13 includes a plurality of thin film transistors 35. The plurality of thin film transistors 35 are provided respectively corresponding to the plurality of pixels 30. In this example, light emission of the pixels 30 is controlled by the respective thin film transistors 35. The pixels 30 and the thin film transistors 35 are combined and arranged in a matrix. That is, in this example, the display device 110 is an active matrix display device based on organic EL.

The driving scheme of the pixels 30 is not limited to the active matrix scheme. For instance, the driving scheme may be the passive matrix scheme or other driving schemes. For instance, in the passive matrix scheme, there is no need to provide a thin film transistor 35 for each pixel 30. That is, the thin film transistor 35 is provided as necessary, and can be omitted.

The thin film transistors 35 are arranged on the first resin layer 11. In this example, the thin film transistors 35 are provided on the first sealing layer 21.

The thin film transistor 35 includes e.g. a first conductive part 41, a second conductive part 42, a gate electrode 43, a gate insulating film 44, a semiconductor layer 45, and a channel protective film 46.

The gate electrode 43 is provided on the first sealing layer 21. The gate electrode 43 is made of e.g. aluminum, copper, molybdenum, tantalum, titanium, or tungsten.

The gate insulating film 44 is provided on the gate electrode 43. In this example, the respective gate insulating films 44 of the plurality of thin film transistors 35 are continuous with each other. In other words, in this example, one gate insulating film is provided entirely on the first sealing layer 21 so as to cover each of the plurality of gate electrodes 43. The gate insulating film 44 is made of e.g. a material having insulating property and optical transmissivity. The gate insulating film 44 is made of e.g. one of silicon oxide film, silicon nitride film, and silicon oxynitride film.

The semiconductor layer 45 is provided on the gate insulating film 44. The gate insulating film 44 is provided between the gate electrode 43 and the semiconductor layer 45, and insulates the gate electrode 43 from the semiconductor layer 45. The semiconductor layer 45 is made of e.g. amorphous silicon. The semiconductor layer 45 may be made of e.g. polysilicon crystallized by laser annealing and the like, an oxide semiconductor such as ZnO and InGaZnO, or an organic semiconductor such as pentacene.

The first conductive part 41 is electrically connected to the semiconductor layer 45. The second conductive part 42 is electrically connected to the semiconductor layer 45. The first conductive part 41 and the second conductive part 42 are made of e.g. Ti, Al, and Mo. The first conductive part 41 and the second conductive part 42 may be made of e.g. a stacked body including at least one of Ti, Al, and Mo. The first conductive part 41 is one of the source electrode and the drain electrode of the thin film transistor 35. The second conductive part 42 is the other of the source electrode and the drain electrode of the thin film transistor 35.

The channel protective film 46 is provided on the semiconductor layer 45. The channel protective film 46 protects the semiconductor layer 45. The channel protective film 46 is made of e.g. silicon oxide film, silicon nitride film, or silicon oxynitride film.

The first conductive part 41 covers part of the semiconductor layer 45. The second conductive part 42 covers another part of the semiconductor layer 45. The semiconductor layer 45 includes a portion not covered with the first conductive part 41 and the second conductive part 42. The gate electrode 43 overlaps the portion between the first conductive part 41 and the second conductive part 42 as projected on the plane parallel to the X-Y plane. Thus, a channel is generated in the semiconductor layer 45 by applying a voltage to the gate electrode 43. Accordingly, a current flows between the first conductive part 41 and the second conductive part 42.

This example is based on the thin film transistor 35 of the bottom gate type in which the semiconductor layer 45 is provided on the gate electrode 43. The thin film transistor 35 is not limited to the bottom gate type. For instance, the thin film transistor 35 may be of the top gate type in which the gate electrode 43 is provided on the semiconductor layer 45.

In this example, the display layer 13 further includes a passivation film 50, a color filter 52, and a bank layer 54.

The passivation film 50 is provided between the thin film transistor 35 and the first electrode 31. The passivation film 50 is made of e.g. a material having insulating property and optical transmissivity. The passivation film 50 is made of e.g. one of silicon oxide film, silicon nitride film, and silicon oxynitride film.

The color filter 52 is provided between the first electrode 31 and the passivation film 50. The color filter 52 has e.g. a different color for each pixel 30. The color filter 52 is made of e.g. a color resin film (e.g., color resist) of one of red, green, and blue. For instance, red, green, and blue color filters 52 are arranged in a prescribed pattern in the respective pixels 30. The light emitted from the organic light emitting layer 33 is transmitted through the color filter 52 and emitted outside from the first resin layer 11 side. Thus, light of a color corresponding to the color filter 52 is emitted from each pixel 30. The color filter 52 is provided as necessary. The color filter 52 can be omitted.

The first electrode 31 is electrically connected to one of the first conductive part 41 and the second conductive part 42. In this example, the first electrode 31 is electrically connected to the first conductive part 41 (e.g., source).

The first electrode 31 is provided on the color filter 52. The first electrode 31 is made of e.g. a material having conductivity and optical transmissivity. The first electrode 31 is made of e.g. ITO (indium tin oxide).

The passivation film 50 and the color filter 52 are each provided with an opening for exposing part of the first conductive part 41. Part of the first electrode 31 is inserted into the respective openings of the passivation film 50 and the color filter 52. The first electrode 31 is electrically connected to the first conductive part 41 in e.g. the portion exposed in the opening of the first conductive part 41. The first electrode 31 is e.g. in contact with the portion exposed in the opening of the first conductive part 41.

The bank layer 54 is provided on the first electrode 31 and the color filter 52. The bank layer 54 is made of e.g. a material having insulating property. The bank layer 54 is made of e.g. an organic resin material. The bank layer 54 is provided with an opening for exposing part of the first electrode 31. For instance, the opening of the bank layer 54 defines the region of each pixel 30.

The organic light emitting layer 33 is provided on the bank layer 54. The organic light emitting layer 33 is e.g. in contact with the first electrode 31 in the opening of the bank layer 54. The organic light emitting layer 33 is made of e.g. a stacked body in which a hole transport layer, a light emitting layer, and an electron transport layer are stacked. In this example, the organic light emitting layers 33 of the respective pixels 30 are continuous with each other. The organic light emitting layer 33 may be provided only in the portion in contact with the first electrode 31. That is, the organic light emitting layer 33 may be provided only in the opening of the bank layer 54.

The second electrode 32 is provided on the organic light emitting layer 33. The second electrode 32 is made of a material having conductivity. The second electrode 32 is made of e.g. Al. In this example, the second electrodes 32 of the respective pixels 30 are continuous with each other. For instance, the second electrodes 32 may be spaced from each other for each pixel 30. For instance, in the case of the passive matrix scheme, the second electrodes 32 of the pixels 30 of a given column are continuous with each other, whereas the second electrodes 32 of different columns are spaced from each other.

The second sealing layer 22 covers the organic light emitting layer 33 and the second electrode 32. The second sealing layer 22 protects e.g. the organic light emitting layer 33 and the second electrode 32. The second sealing layer 22 is made of e.g. one of silicon oxide film, silicon oxynitride film, silicon nitride film, alumina, and tantalum oxide film. The second sealing layer 22 is made of e.g. a stacked film thereof.

The second resin layer 12 can be made of e.g. substantially the same material as the first resin layer 11. The second resin layer 12 is made of e.g. polyimide. The material of the second resin layer 12 may be different from the material of the first resin layer 11. In this example, the second resin layer 12 does not need to have optical transmissivity. For instance, in the case of a display device of the top emission type, the second resin layer 12 is made of an optically transmissive material. The bonding layer 14 is made of e.g. a photosetting resin material or thermosetting resin material.

Next, a method for manufacturing the display device 110 is described.

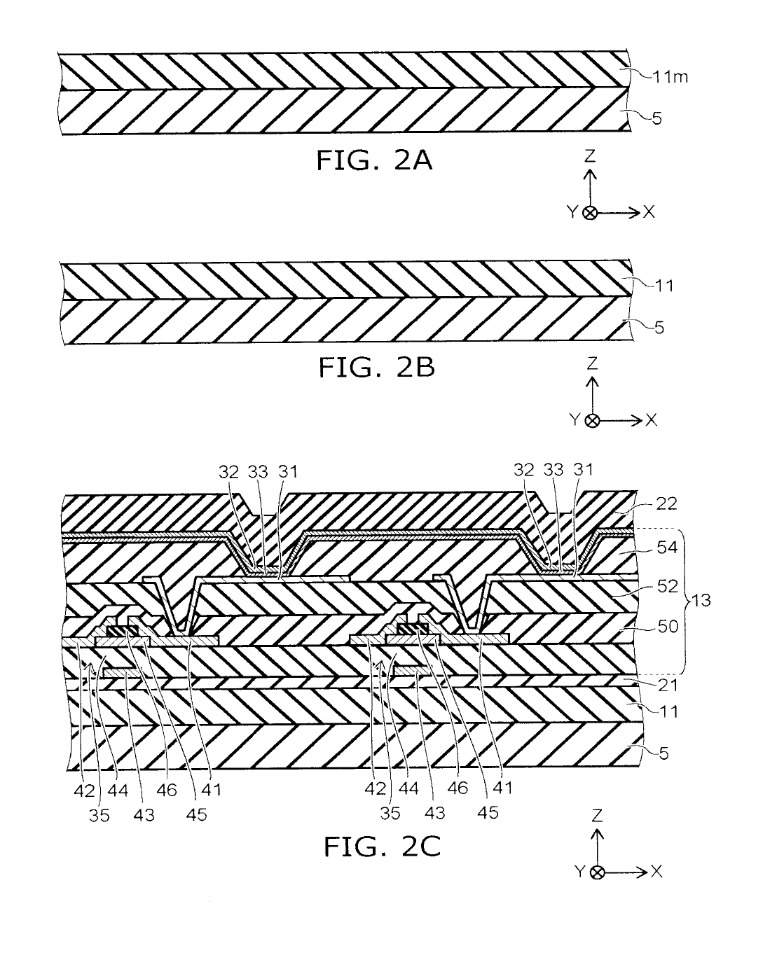

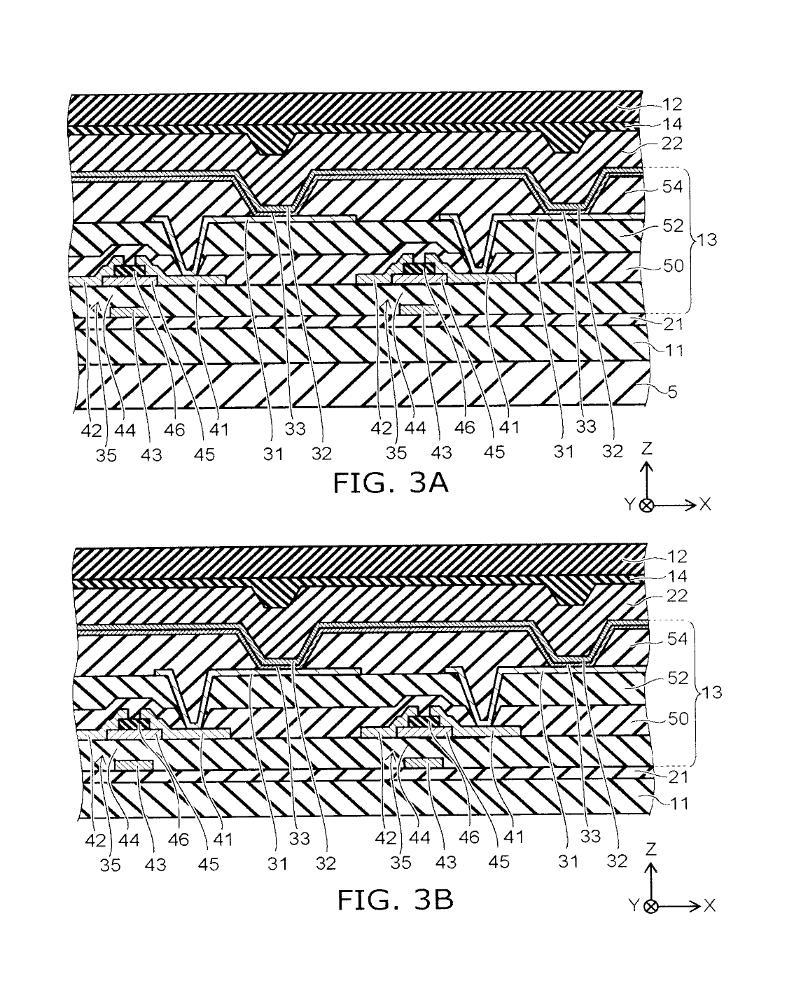

FIGS. 2A to 2C, 3A, and 3B are sectional views schematically showing a sequential process for manufacturing a display device according to the first embodiment.

As shown in FIGS. 2A and 2B, in the manufacturing of the display device 110, first, a first resin layer 11 is formed on a substrate 5.

In forming the first resin layer 11, for instance, a material layer 11m including the raw material of the first resin layer 11 is formed on the substrate 5. Subsequently, the material layer 11m is heated. Thus, a first resin layer 11 is formed from the material layer 11m. The substrate 5 is e.g. a glass substrate.

Formation of polyimide film as an example of the first resin layer 11 is now briefly described. In the case where the first resin layer 11 is made of polyimide film, a heat-resistant resin including a polymer having an imide group in its structure is used. Examples of the polyimide resin include polyamide-imide, polybenzimidazole, polyimide ester, polyether imide, and polysiloxane-imide.

The polyimide resin can be produced by reaction of known diamine and acid anhydride in the presence of a solvent. For instance, a resin solution of polyamic acid, which is a precursor of the polyimide resin, can be obtained by reaction of diamine and acid anhydride.

The substrate 5 functions as e.g. a support body for applying a polyamic acid solution. The moisture permeability of the substrate 5 affects the peelability of the polyimide resin being formed. For instance, the organic solvent in the step for drying and imidizing the polyamic acid solution and the moisture associated with the progress of imidization concentrate at the interface between the substrate 5 and the first resin layer 11 and hamper the adherence therebetween. In this state, for instance, the substrate 5 is easily peeled from the first resin layer 11. That is, high moisture permeability of the substrate 5 prevents moisture from remaining at the interface and enhances the adherence. On the other hand, if the moisture permeability is too low, the moisture is insufficiently eliminated and tends to cause unexpected floating of the first resin layer 11 during the process.

Imidization is a step for advancing cyclodehydration of polyamic acid by heat treatment to form polyimide. That is, imidization is the step for forming the first resin layer 11 from the material layer 11m. As described above, the peelability of the substrate 5 is significantly affected by how much amount of imidization water generated in the imidization is left at the interface between the substrate 5 and the first resin layer 11. If the liquid component at the interface is completely removed, the adherence becomes robust and causes peeling failure. In the case of lowering the adhering strength by inserting a peeling layer, it is supposed that, for instance, the peeling layer is made of a material such that imidization moisture remains at the interface with the peeling layer.

As shown in FIG. 2C, a first sealing layer 21 is formed on the first resin layer 11. Then, a display layer 13 is formed on the first sealing layer 21. In this embodiment, for instance, the display layer 13 can be manufactured in the same way as the existing process on the glass substrate. For instance, a display including an array of the active matrix display can be fabricated on the first resin layer 11 using the existing technique.

For instance, a metal layer may be formed on the first resin layer 11, and a first sealing layer 21 may be formed on the metal layer. A contact with the metal layer is formed by forming a through hole in the first sealing layer 21 before forming the gate electrode 43. Thus, for instance, mounting from the back side is enabled by the laser peeling process performed later. Subsequently, an active matrix basically similar to the conventional one may be formed. For instance, a method for forming an active matrix based on amorphous TFT (thin film transistor) is now illustrated.

First, a gate electrode 43 is formed. The gate electrode is made of e.g. at least one of aluminum, copper, molybdenum, tantalum, titanium, and tungsten. The gate electrode 43 is electrically connected to e.g. the driver IC through a contact hole and a wiring.

Next, a gate insulating film 44 is formed. The gate insulating film 44 is formed by e.g. CVD technique or sputtering technique. The gate insulating film 44 is made of e.g. SiO, SiN, or SiON.

Next, a semiconductor layer 45 is formed. The semiconductor layer 45 is formed by e.g. CVD technique. The semiconductor layer 45 is made of e.g. hydrogenated amorphous silicon (a-Si:H). Next, a channel protective film 46 is formed. The channel protective film 46 is formed by e.g. CVD technique or sputtering technique. The channel protective film 46 is made of e.g. SiO, SiN, or SiON. Then, a first conductive part 41 and a second conductive part 42 are formed. Thus, a thin film transistor 35 is formed.

Subsequently, formation of a passivation film 50, formation of a contact hole, formation of a first electrode 31, formation of a bank layer 54, formation of an organic light emitting layer 33, and formation of a second electrode 32 are sequentially performed. Thus, a display layer 13 is formed. Then, a second sealing layer 22 is formed on the second electrode 32. The second sealing layer 22 is made of e.g. a stacked film including SiN or AlO. The method for forming the thin film transistor 35 and the structure of the thin film transistor 35 are not limited to the foregoing. For instance, the channel protective film 46 may be omitted in the thin film transistor.

In the formation of the organic light emitting layer 33, for instance, a hole transport layer is evaporated, and a light emitting layer is deposited. An electron transport layer is formed on the light emitting layer. The second electrode 32 is made of e.g. a stacked film of LiF and Al. The second sealing layer 22 may be made of e.g. SiNₓ formed by PE-CVD technique, SiOₓ formed by sputtering technique, or an organic resin film (parylene) including polyparaxylene.

As shown in FIG. 3A, a second resin layer 12 is bonded onto the display layer 13 via a bonding layer 14. In this example, the second resin layer 12 is bonded to the second sealing layer 22. This can improve e.g. the sealing performance. Furthermore, the second resin layer 12 also functions as a support body for the display layer 13 and the like when the substrate 5 is removed by laser peeling or the like.

As shown in FIG. 3B, the substrate 5 is removed. The substrate 5 is removed by e.g. laser peeling. In laser peeling, laser light is applied from the substrate 5 side to cause the first resin layer 11 or an absorption layer (not shown) to absorb the light. Thus, heat is generated in a very small region. Accordingly, the substrate 5 is peeled from the first resin layer 11.

The laser light is restricted in terms of wavelength. It is necessary to select laser light having a center wavelength transmitted through the substrate 5 (e.g., glass) and absorbed in the first resin layer 11 (e.g., polyimide). Candidates include e.g. XeCl excimer laser (center wavelength 308 nm) and YAG:THG laser (center wavelength 355 nm).

In another scheme, light is absorbed in an absorption layer even if there is no absorption in the first resin layer 11. In this case, a metal film used as the absorption layer has absorption in a wide wavelength range. This expands the range of choices for available lasers. For instance, the metal film is made of Ti, and an infrared fiber laser is used as the laser. The XeCl excimer laser is very expensive in the apparatus cost and running cost. Thus, in view of reducing the process cost in the future, it is considered that the manufacturing cost can be suppressed even with an additional process for providing an absorption layer.

The removal of the substrate 5 is not limited to laser peeling. For instance, the substrate 5 may be peeled from the first resin layer 11 by heating the first resin layer 11 with a lamp or the like. Alternatively, for instance, the substrate 5 may be removed by grinding the substrate 5. Alternatively, for instance, the substrate 5 may be removed by dissolving the adhesive between the substrate 5 and the first resin layer 11 with a chemical agent or the like.

After removing the substrate 5, the step for increasing the density of the bonding layer 14 is performed. The “step for increasing the density of the bonding layer 14” is, in other words, the step for decreasing the intermolecular distance of the material of the bonding layer 14. For instance, it can also be referred to as the process of increasing the elasticity. More specifically, for instance, it is the step for curing the bonding layer 14 by heat or light. For instance, in the case where the bonding layer 14 is made of a photosetting resin material, the density of the bonding layer 14 is increased by irradiating the bonding layer 14 with light. That is, the bonding layer 14 is cured by irradiation with light. For instance, in the case where the bonding layer 14 is made of a thermosetting resin material, the density of the bonding layer 14 is increased by heating the bonding layer 14. That is, the bonding layer 14 is cured by heating.

Thus, the display device 110 is completed.

After removing the substrate 5, the bonding layer 14 is cured by heat or light. Thus, for instance, the bonding layer 14 develops barrier property. In this embodiment, the bonding layer 14 is not cured before removing the substrate 5. In contrast, the bonding layer 14 is cured after removing the substrate 5. This can avoid e.g. stress concentration on the organic light emitting layer 33. The organic light emitting layer 33 has low interlayer adhesiveness. Thus, film peeling occurs in the organic light emitting layer 33 under concentration of force. The pixel 30 subjected to film peeling lacks EL light emission and results in a dark spot. Thus, it is very important to suppress the film stress applied to the organic light emitting layer 33.

For instance, a film may be laminated on the surface of the first resin layer 11 on the side opposite from the display layer 13 to strike a balance between the second resin layer 12 and the second sealing layer 22. Thus, the organic light emitting layer 33 may be positioned as close to the neutral plane as possible. That is, the position in the Z-axis direction of the organic light emitting layer 33 is placed near the center of thickness in the Z-axis direction of the display device 110. Thus, the stress applied to the organic light emitting layer 33 can be decreased e.g. when the flexible display device 110 is warped. For instance, the display device 110 can be provided with a structure resistant to bending.

The foregoing has described only the process characteristic of the display device 110 according to this embodiment. However, this does not exclude processes other than the foregoing, but any process can be included.

The inventor formed the display layer 13 on a polyimide film (10 μm) applied on a glass substrate (film thickness 700 μm). Samples laminated with a PEN substrate as the second resin layer 12 were fabricated, and evaluation of peeling using XeCl excimer laser was performed.

In the peeling evaluation, three samples different in the type of the bonding layer 14 were fabricated. In the first sample, the bonding layer 14 was made of a material serving only for bonding. In the second sample, the bonding layer 14 was made of a material subjected to thermosetting after bonding. In the third sample, the bonding layer 14 was made of a thermoplastic adhesive.

The first sample and the third sample were not affected by the overlap ratio even under the peeling condition of laser irradiation. EL light emission was achieved in both samples. Here, the overlap ratio refers to the proportion of the overlapping area of the portion subjected to the first laser shot and the portion subjected to the second laser shot versus the area of the portion subjected to the first laser shot. On the other hand, the second sample was significantly affected by the overlap ratio in the case where laser peeling was performed after curing the bonding layer 14.

Thus, in the case of high overlap ratio, the organic light emitting layer 33 of the pixel 30 was subjected to film peeling, and exhibited high residual stress. Normal lighting of the pixel 30 was confirmed before peeling. For instance, by the removal of the glass substrate serving as a support body, the first resin layer 11 constitutes the outermost surface, and the residual stress is relaxed. Thus, in the process in which the first resin layer 11 changes its own shape, a large stress is applied to the edge of the bank structure part of the organic light emitting layer 33. It is considered that this causes film peeling.

Irrespective of whether peeling is performed mechanically by hands or tools, or by laser irradiation, a large stress occurs at the interface between the peeled region and the adhering region yet to be peeled. This continuously moves with the progress of peeling. Thus, whether film peeling occurs at the moment of peeling is determined by the balance between the structure and the stress. From the foregoing, it turns out that the influence of residual stress of the second resin layer 12 and the bonding layer 14 is significant. Thus, it is important to remove the substrate 5 when the residual stress of the bonding layer 14 is made as small as possible.

Thus, the inventor has found that the residual stress of the bonding layer 14 affects the film peeling of the organic light emitting layer 33 in the step for removing the substrate 5. This is a technical problem that has first been found by the inventor's investigation.

Furthermore, the inventor evaluated the above samples also in terms of gas barrier property. As a result, it has turned out that the gas barrier property of the first sample and the third sample is lower than the gas barrier property of the second sample.

Thus, in the case where the bonding layer 14 is made of a material serving only for bonding, and in the case where the bonding layer 14 is made of a thermoplastic material, film peeling of the organic light emitting layer 33 can be suppressed, but the gas barrier property is low. On the other hand, in the method of peeling the bonding layer 14 from the substrate 5 after curing the bonding layer 14, a good gas barrier property is achieved, but film peeling of the organic light emitting layer 33 is likely to occur.

In contrast, in the method for manufacturing the display device 110 according to this embodiment, the substrate 5 is removed when the bonding layer 14 has low density. Specifically, the substrate 5 is removed before curing the bonding layer 14. Thus, the stress applied to the organic light emitting layer 33 in the step for removing the substrate 5 can be made smaller than in the case of removing the substrate 5 after curing the bonding layer 14. This can suppress e.g. film peeling of the organic light emitting layer 33 in the step for removing the substrate 5. Furthermore, a good gas barrier property can also be achieved by increasing the density of the bonding layer 14 after removing the substrate 5.

Thus, the method for manufacturing the display device 110 according to this embodiment can achieve high reliability. For instance, suppression of film peeling of the organic light emitting layer 33 can be made compatible with high gas barrier property. For instance, the display device 110 can be manufactured with higher yield. For instance, the manufacturing cost can be suppressed.

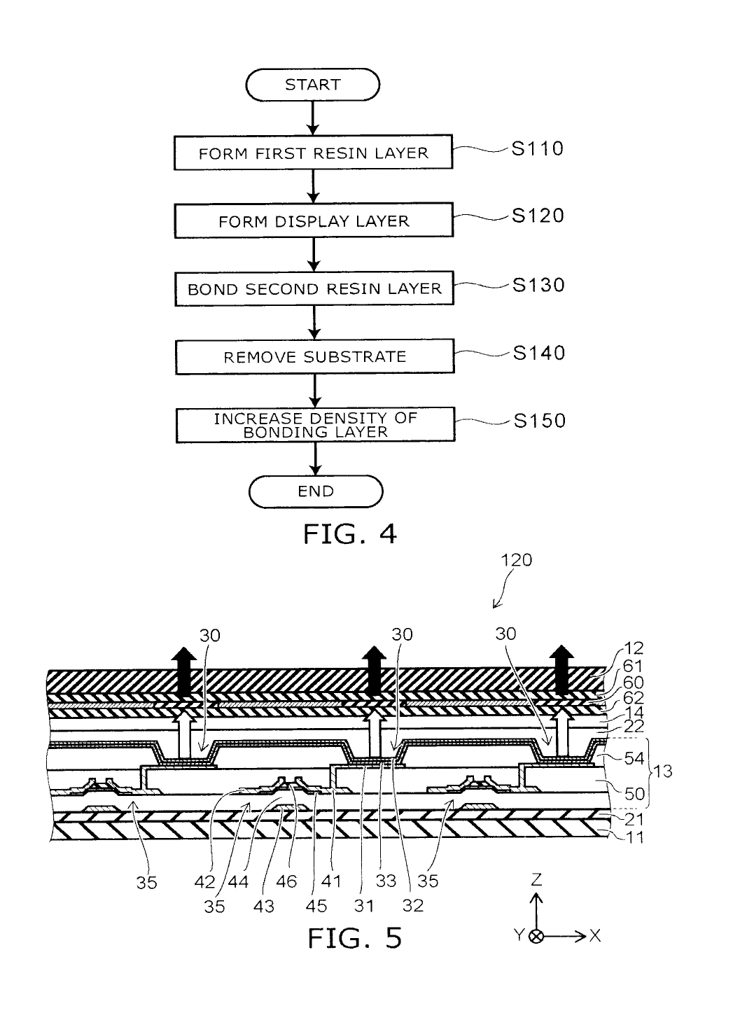

FIG. 4 is a flow chart schematically showing the method for manufacturing a display device according to the first embodiment.

As shown in FIG. 4, the method for manufacturing a display device according to the embodiment includes a step S110 for forming a first resin layer 11, a step S120 for forming a display layer 13, a step S130 for bonding a second resin layer 12, a step S140 for removing the substrate 5, and a step S150 for increasing the density of the bonding layer 14. The method for manufacturing a display device according to the embodiment may further include other steps. For instance, the step S110 for forming the first resin layer 11 may include a step for forming a material layer 11m and a step for forming the first resin layer 11 from the material layer 11m.

The step S110 performs e.g. the processing described with reference to FIGS. 2A and 2B. The step S120 performs e.g. the processing described with reference to FIG. 2C. The step S130 performs e.g. the processing described with reference to FIG. 3A. The step S140 and the step S150 perform e.g. the processing described with reference to FIG. 3B.

Thus, a method for manufacturing a display device with high reliability can be obtained.

### Second Embodiment

FIG. 5 is a sectional view schematically showing a display device according to a second embodiment.

As shown in FIG. 5, in the display device 120, a color filter layer 60 is provided between the second resin layer 12 and the bonding layer 14. Furthermore, the display device 120 further includes a planarization layer 61 provided between the second resin layer 12 and the color filter layer 60, and a barrier layer 62 provided between the bonding layer 14 and the color filter layer 60. In the display device 120, the color filter layer 60, the planarization layer 61, and the barrier layer 62 are provided as necessary, and can be omitted. The members similar to those in the above first embodiment are labeled with like reference numerals, and the detailed description thereof is omitted.

In the display device 120, the second electrode 32 has optical transmissivity. In the display device 120, the second electrode 32 is e.g. a transparent electrode. The first electrode 31 is e.g. optically reflective. The first electrode 31 may be optically transmissive. That is, the display device 120 is of the top emission type in which the light emitted from the organic light emitting layer 33 is transmitted through the second electrode 32 and emitted outside from the second resin layer 12 side. Thus, in the display device 120, each of the second sealing layer 22, the bonding layer 14, the barrier layer 62, the color filter layer 60, the planarization layer 61, and the second resin layer 12 also has optical transmissivity.

In this example, the first electrode 31 is made of e.g. LiF/AI, Al, or Ag. The second electrode 32 is made of e.g. ITO or MgAg. The planarization layer 61 is made of e.g. silicon oxide film, silicon nitride film, silicon oxynitride film, or aluminum oxide film. The barrier layer 62 is made of e.g. silicon oxide film, silicon nitride film, silicon oxynitride film, or aluminum oxide film.

The color filter layer 60 includes e.g. a plurality of color filters 60a. The color filters 60a are placed at e.g. positions overlapping the respective pixels 30 as projected on the plane parallel to the X-Y plane. Thus, the light emitted from the organic light emitting layer 33 is transmitted through the color filter 60a. Accordingly, light of a color corresponding to the color filter 60a is emitted outside.

The color filter layer 60 further includes e.g. a light blocking part 60b. The light blocking part 60b has no optical transmissivity. The light blocking part 60b is shaped like e.g. a frame surrounding each of the color filters 60a. For instance, the light blocking part 60b overlaps each of the thin film transistors 35 as projected on the plane parallel to the X-Y plane. This can suppress e.g. incidence of external light on the thin film transistors 35. Thus, characteristics variation of the thin film transistors 35 can be suppressed. The light blocking part 60b is made of e.g. a black resin material.

Next, a method for manufacturing the display device 120 is described.

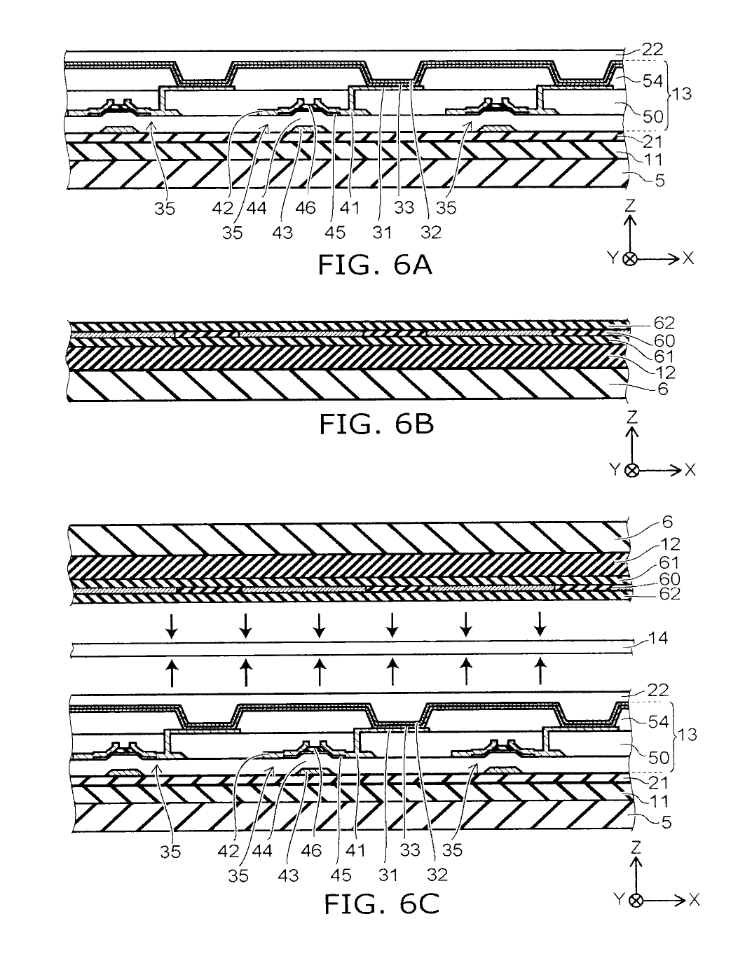

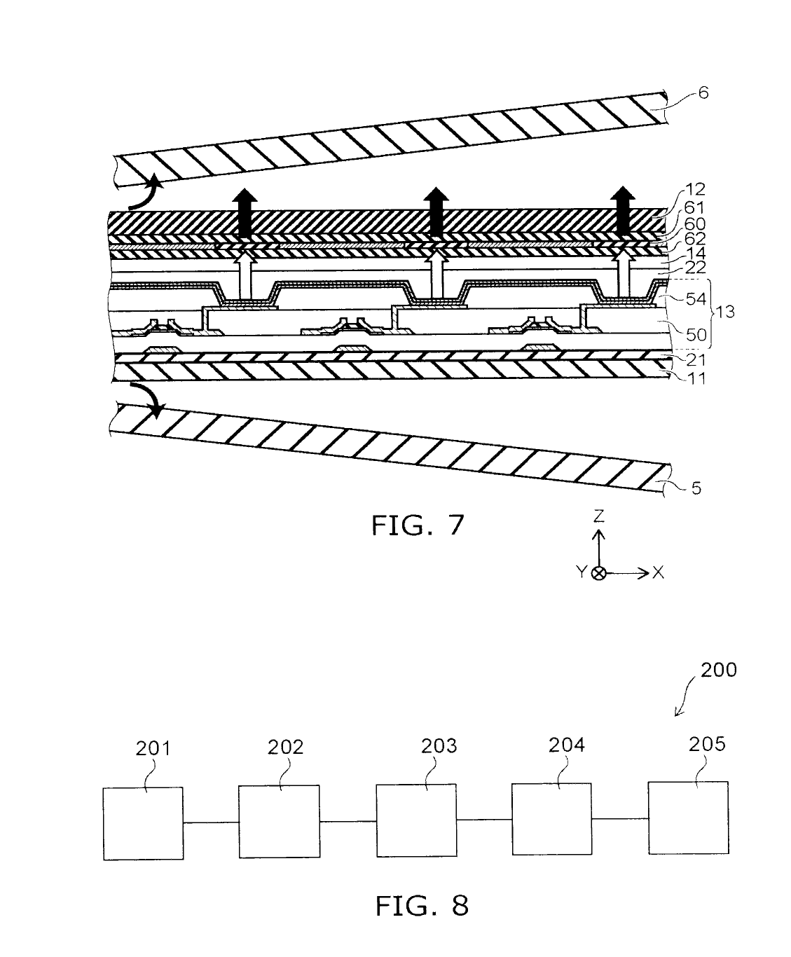

FIGS. 6A to 6C, and 7 are sectional views schematically showing a sequential process for manufacturing a display device according to the second embodiment.

As shown in FIG. 6A, in the manufacturing of the display device 120, first, a first resin layer 11 is formed on a substrate 5 as in the above first embodiment. A first sealing layer 21 is formed on the first resin layer 11. A display layer 13 is formed on the first sealing layer 21. Then, a second sealing layer 22 is formed on the display layer 13.

As shown in FIG. 6B, besides the display layer 13 and the like, a second resin layer 12 is formed on a support body 6. The support body 6 is made of e.g. a glass substrate. The step for forming the second resin layer 12 on the support body 6 may be performed before the step for forming the first resin layer 11 on the substrate 5. Alternatively, the step for forming the first resin layer 11 on the substrate 5 and the step for forming the second resin layer 12 on the support body 6 may be performed substantially at the same time.

A color filter layer 60 is formed on the second resin layer 12. In this example, a planarization layer 61 is formed on the second resin layer 12, and a color filter layer 60 is formed on the planarization layer 61. Then, a barrier layer 62 is formed on the color filter layer 60.

As shown in FIG. 6C, the second resin layer 12 is bonded onto the display layer 13 via a bonding layer 14. In this example, the color filter layer 60 and the second resin layer 12 are bonded onto the display layer 13 via the bonding layer 14 so that the color filter layer 60 is placed between the display layer 13 and the second resin layer 12. In this example, the barrier layer 62 is bonded to the second sealing layer 22 by the bonding layer 14.

As shown in FIG. 7, the substrate 5 is removed by e.g. irradiation with laser light. Then, in this example, the support body 6 is further removed. The removal of the support body 6 can be based on e.g. a method similar to the removal of the substrate 5. Subsequently, the step for increasing the density of the bonding layer 14 is performed as in the first embodiment. Thus, the display device 120 is completed.

Thus, in the display device 120 of the top emission type, the step for increasing the density of the bonding layer 14 is performed after removing the substrate 5 and removing the support body 6. This can suppress e.g. film peeling of the organic light emitting layer 33 in the step for removing the substrate 5 and the step for removing the support body 6. Furthermore, a good gas barrier property can also be achieved by increasing the density of the bonding layer 14 after removing the substrate 5 and the support body 6.

### Third Embodiment

FIG. 8 is a block diagram schematically showing a manufacturing system according to a third embodiment.

As shown in FIG. 8, the manufacturing system 200 includes a first processing unit 201, a second processing unit 202, a third processing unit 203, a fourth processing unit 204, and a fifth processing unit 205.

The first processing unit 201 performs the processing for forming a first resin layer 11 on a substrate 5. The first processing unit 201 performs e.g. the processing described with reference to FIGS. 2A and 2B.

The second processing unit 202 performs the processing for forming a display layer 13 on the first resin layer 11. The second processing unit 202 performs e.g. the processing described with reference to FIG. 2C.

The third processing unit 203 performs the processing for bonding a second resin layer onto the display layer 13 via a bonding layer 14. The third processing unit 203 performs e.g. the processing described with reference to FIG. 3A.

The fourth processing unit 204 performs the processing for removing the substrate 5. The fourth processing unit 204 performs e.g. the processing described with reference to FIG. 3B.

The fifth processing unit 205 performs the processing for increasing the density of the bonding layer 14. The fifth processing unit 205 performs e.g. the processing described with reference to FIG. 3B.

The first to fifth processing units 201-205 may be configured in a single apparatus, or may be configured in separate apparatuses. Each of the first to fifth processing units 201-205 may include a plurality of apparatuses. For instance, the first processing unit 201 may include an apparatus for forming a material layer 11m and an apparatus for forming the first resin layer 11 from the material layer 11m.

The manufacturing system 200 may further include e.g. a transport apparatus for transporting a workpiece such as the substrate 5 among the first to fifth processing units 201 205. The transport of the workpiece among the first to fifth processing units 201-205 may be performed e.g. manually by an operator or the like.

The embodiments provide a method and system for manufacturing a display device having high reliability.

In this specification, “perpendicular” and “parallel” mean not only being exactly perpendicular and exactly parallel, but include e.g. variations in the manufacturing process, and only need to mean being substantially perpendicular and substantially parallel. In this specification, the state of being “provided on” includes not only the state of being provided in direct contact, but also the state of being provided with another element interposed in between. The state of being “stacked” includes not only the state of being stacked in contact with each other, but also the state of being stacked with another element interposed in between. The state of being “opposed” includes not only the state of directly facing, but also indirectly facing with another element interposed in between. In this specification, “electrically connected” includes not only the case of being connected by direct contact, but also the case of being connected via another conductive member and the like.

The embodiments of the invention have been described above with reference to examples.

However, the embodiments of the invention are not limited to these examples. For instance, any specific configurations of various components such as the substrate, first resin layer, display layer, pixel, first electrode, organic light emitting layer, second electrode, bonding layer, and material layer included in the display device, and the first to fifth processing units included in the manufacturing system are encompassed within the scope of the invention as long as those skilled in the art can similarly practice the invention and achieve similar effects by suitably selecting such configurations from conventionally known ones.

Furthermore, any two or more components of the examples can be combined with each other as long as technically feasible. Such combinations are also encompassed within the scope of the invention as long as they fall within the spirit of the invention.

Moreover, all manufacturing methods and manufacturing systems for display device practicable by an appropriate design modification by one skilled in the art based on the manufacturing methods and the manufacturing systems for display device described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a display device, comprising:
forming a first resin layer on a substrate;
forming a display layer on the first resin layer, the display layer including a plurality of pixels arranged in a direction perpendicular to a stacking direction of the first resin layer and the display layer, each of the pixels including a first electrode provided on the first resin layer, an organic light emitting layer provided on the first electrode, and a second electrode provided on the organic light emitting layer;
bonding a second resin layer onto the display layer via a bonding layer;
removing the substrate; and
increasing a density of the bonding layer.

2. The method according to claim 1, wherein the forming the first resin layer includes:
forming a material layer on the substrate; and
forming the first resin layer from the material layer by heating the material layer.

3. The method according to claim 1, wherein the first resin layer includes polyimide.

4. The method according to claim 1, wherein the removing the substrate includes peeling the substrate from the first resin layer by irradiating the first resin layer with a laser light.

5. The method according to claim 1, wherein the removing the substrate includes peeling the substrate from the first resin layer by heating the first resin layer.

6. The method according to claim 1, wherein the increasing the density of the bonding layer includes curing the bonding layer by irradiating the bonding layer with a light.

7. The method according to claim 1, wherein the increasing the density of the bonding layer includes curing the bonding layer by heating the bonding layer.

8. The method according to claim 1, further comprising:
forming the second resin layer on a support body and forming a color filter layer on the second resin layer,
wherein the bonding the second resin layer includes bonding the color filter layer and the second resin layer onto the display layer via the bonding layer, the color filter layer is placed between the display layer and the second resin layer.

9. The method according to claim 1, wherein the forming the display layer further includes forming a first sealing layer on the first resin layer and forming the display layer on the first sealing layer.

10. The method according to claim 9, wherein
the forming the display layer further includes forming a second sealing layer on the display layer, and
the bonding the second resin layer includes bonding the second resin layer onto the second sealing layer.

11. A system for manufacturing a display device, comprising:
a first processing unit configured to form a first resin layer on a substrate;
a second processing unit configured to form a display layer on the first resin layer, the display layer including a plurality of pixels arranged in a direction perpendicular to a stacking direction of the first resin layer and the display layer, each of the pixels including a first electrode provided on the first resin layer, an organic light emitting layer provided on the first electrode, and a second electrode provided on the organic light emitting layer;
a third processing unit configured to bond a second resin layer onto the display layer via a bonding layer;
a fourth processing unit configured to remove the substrate; and
a fifth processing unit configured to increase a density of the bonding layer.

12. The system according to claim 11, wherein the first processing unit forms a material layer on the substrate and forms the first resin layer from the material layer by heating the material layer.

13. The system according to claim 11, wherein the first resin layer includes polyimide.

14. The system according to claim 11, wherein the fourth processing unit peels the substrate from the first resin layer by irradiating the first resin layer with a laser light.

15. The system according to claim 11, wherein the fourth processing unit peels the substrate from the first resin layer by heating the first resin layer.

16. The system according to claim 11, wherein the fifth processing unit cures the bonding layer by irradiating the bonding layer with a light.

17. The system according to claim 11, wherein the fifth processing unit cures the bonding layer by heating the bonding layer.

18. The system according to claim 11, wherein the third processing unit forms the second resin layer on a support body, forms a color filter layer on the second resin layer, and bonds the color filter layer and the second resin layer onto the display layer via the bonding layer, the color filter layer is placed between the display layer and the second resin layer.

19. The system according to claim 11, wherein the second processing unit forms a first sealing layer on the first resin layer and forms the display layer on the first sealing layer.

20. The system according to claim 19, wherein
the second processing unit forms a second sealing layer on the display layer, and
the third processing unit bonds the second resin layer onto the second sealing layer.
